(19) United States
(12) Patent Application Publication
(10) Pub. No.: US 2018/0337234 A1
(43) Pub. Date: Nov. 22, 2018

(54) SEMICONDUCTOR DEVICE AND MANUFACTURING METHOD THEREFOR

(71) Applicants: Semiconductor Manufacturing International (Shanghai) Corporation, Shanghai (CN); Semiconductor Manufacturing International (Beijing) Corporation, Beijing (CN)

(72) Inventor: Meng Zhao, Shanghai (CN)

(73) Assignees: Semiconductor Manufacturing International (Shanghai) Corporation, Shanghai (CN); Semiconductor Manufacturing International (Beijing) Corporation, Beijing (CN)

(21) Appl. No.: 15/976,070

(22) Filed: May 10, 2018

(30) Foreign Application Priority Data
May 19, 2017 (CN) 201710355386.1

(51) Int. Cl. H01L 29/08; H01L 29/78; H01L 29/417; H01L 29/66

(52) U.S. Cl. CPC H01L 29/0847; H01L 29/6681; H01L 29/41783; H01L 29/785

(57) ABSTRACT

The present disclosure relates to the technical field of semiconductors, and discloses a semiconductor device and a manufacturing method therefor. The semiconductor device includes: a semiconductor substrate; a semiconductor fin on the semiconductor substrate; a gate structure on the semiconductor fin; a first recess and a second recess in the semiconductor fin and respectively at two sides of the gate structure; a diffusion barrier layer located at a bottom portion and a side wall of at least one recess of the first recess and the second recess; and an electrode on the diffusion barrier layer. In forms of the present disclosure, a diffusion barrier layer is formed on a bottom portion and a side wall of a recess of a semiconductor device; an electrode is formed on the diffusion barrier layer; and the diffusion barrier layer may possibly reduce a possibility that P-typed dopants or N-typed dopants in the electrode are diffused to a channel region, so as to possibly avoid decreasing a charge carrier mobility of the channel region, and improve the SCE, thereby improving performance of the device.

### RELATED APPLICATIONS

The present application claims priority to Chinese Patent Appln. No. 201710355386.1, filed May 19, 2017, the entire disclosure of which is hereby incorporated by reference.

### BACKGROUND

### Technical Field

The present disclosure relates to the technical field of semiconductors, and in particular, to a semiconductor device and a manufacturing method therefor.

### Related Art

As semiconductor devices become smaller, a short channel effect (“SCE”) has become an urgent problem to be resolved. To improve the SCE of a core device, an ultra-shallow junction and an abrupt junction may be established.

To enhance a performance of a device, a direction of a next generation of technology is using a FinFET (Fin Field-Effect Transistor) device, where the FinFET device may alleviate the SCE. However, a source region, a drain region, and a halo doping region of the FinFET diffuse some dopants to a channel region, causing low doping of the channel region. This reduces a charge carrier mobility of the channel region, and increases a leakage current. At present, the performance of the device may be improved by optimizing the LDD (Lightly Doped Drain) and the halo doping profiles. However, effects of these methods are limited.

### SUMMARY

The inventor of the present disclosure finds that the foregoing prior art has problems, and provides a new technical solution regarding at least one of the foregoing problems.

In a first aspect of the present disclosure, a semiconductor device is provided. The semiconductor device may include: a semiconductor substrate; a semiconductor fin on the semiconductor substrate; a gate structure on the semiconductor fin; a first recess and a second recess in the semiconductor fin and positioned respectively at two sides of the gate structure; a diffusion barrier layer located at a bottom portion and a side wall of at least one recess of the first recess and the second recess; and an electrode on the diffusion barrier layer.

In some implementations, the diffusion barrier layer includes at least one of carbon or nitrogen.

In some implementations, in the diffusion barrier layer, a doping density of the carbon is from 1×10¹⁸ atom/cm³ to 1×10²⁰ atom/cm³; and in the diffusion barrier layer, a doping density of the nitrogen is from 1×10¹⁹ atom/cm³ to 1×10²⁰ atom/cm³.

In some implementations, the diffusion barrier layer is formed at bottom portions and side walls of the first recess and the second recess; and the electrode includes: a raised source that is on the diffusion barrier layer and fills the first recess, and a raised drain that is on the diffusion barrier layer and fills the second recess.

In some implementations, the diffusion barrier layer includes: at least one of a first diffusion barrier layer containing nitrogen or a second diffusion barrier layer containing carbon.

In some implementations, the first diffusion barrier layer is at the bottom portions and the side walls of the first recess and the second recess, and the second diffusion barrier layer is on the first diffusion barrier layer; or the second diffusion barrier layer is at the bottom portions and the side walls of the first recess and the second recess, and the first diffusion barrier layer is on the second diffusion barrier layer.

In some implementations, a conductivity type of the diffusion barrier layer is the same as a conductivity type of the electrode.

In some implementations, a thickness range of the diffusion barrier layer is from 8 nm to 35 nm; a thickness range of the first diffusion barrier layer is from 4 nm to 16 nm; and a thickness range of the second diffusion barrier layer is from 4 nm to 16 nm.

In some implementations, the gate structure includes: a gate dielectric layer on a portion of the semiconductor fin, a gate on the gate dielectric layer, and a spacer on a side surface of the gate.

In some implementations, the electrode includes at least one of carbon or nitrogen.

In some implementations, injection depths of the at least one of carbon or nitrogen in the electrode are from 1 nm to 20 nm, respectively; and injection concentrations of the at least one of carbon or nitrogen in the electrode are from 1×10¹⁹ atom/cm³ to 5×10²⁰ atom/cm³, respectively.

The foregoing semiconductor device includes a diffusion barrier layer on a bottom portion and a side wall of a recess, where an electrode is formed on the diffusion barrier layer. The diffusion barrier layer may reduce a possibility that P-typed dopants or N-typed dopants in the electrode are diffused to a channel region, and possibly avoid low doping of the channel region, so as to avoid decreasing a charge carrier mobility of the channel region. Therefore, a stronger working current (that is, a channel current) may be generated when the semiconductor device is working, the SCE may be improved, and a leakage current may be decreased, so as to improve performance of the device.

In another aspect of the present disclosure, a method for manufacturing a semiconductor device is provided. The method may include: providing a semiconductor structure, where the semiconductor structure includes: a semiconductor substrate, a semiconductor fin on the semiconductor substrate, and a gate structure on the semiconductor fin; forming a first recess and a second recess in the semiconductor fin and respectively at two sides of the gate structure; forming a diffusion barrier layer at a bottom portion and a side wall of at least one recess of the first recess and the second recess; and forming an electrode on the diffusion barrier layer.

In some implementations, the diffusion barrier layer includes at least one of carbon or nitrogen.

In some implementations, in the diffusion barrier layer, a doping density of the carbon is from 1×10¹⁸ atom/cm³ to 1×10²⁰ atom/cm³; and in the diffusion barrier layer, a doping density of the nitrogen is from 1×10¹⁹ atom/cm³ to 1×10²⁰ atom/cm³.

In some implementations, the step of forming a diffusion barrier layer at a bottom portion and a side wall of at least one recess of the first recess and the second recess includes: forming the diffusion barrier layer at bottom portions and side walls of the first recess and the second recess; and the step of forming an electrode on the diffusion barrier layer includes: forming, on the diffusion barrier layer, a raised source that fills the first recess, and forming, on the diffusion barrier layer, a raised drain that fills the second recess.

In some implementations, the diffusion barrier layer includes at least one of a first diffusion barrier layer containing nitrogen or a second diffusion barrier layer containing carbon.

In some implementations, the step of forming the diffusion barrier layer at the bottom portions and the side walls of the first recess and the second recess includes: forming, by means of an epitaxial process, the first diffusion barrier layer at the bottom portions and the side walls of the first recess and the second recess, and forming, by means of the epitaxial process, the second diffusion barrier layer on the first diffusion barrier layer; or forming, by means of the epitaxial process, the second diffusion barrier layer at the bottom portions and the side walls of the first recess and the second recess, and forming, by means of the epitaxial process, the first diffusion barrier layer on the second diffusion barrier layer.

In some implementations, a conductivity type of the diffusion barrier layer is the same as a conductivity type of the electrode.

In some implementations, a thickness range of the diffusion barrier layer is from 8 nm to 35 nm; a thickness range of the first diffusion barrier layer is from 4 nm to 16 nm; and a thickness range of the second diffusion barrier layer is from 4 nm to 16 nm.

In some implementations, the gate structure includes: a gate dielectric layer on a portion of the semiconductor fin, a gate on the gate dielectric layer, and a spacer on a side surface of the gate.

In some implementations, the method further includes: performing an ion injection on the electrode, so as to inject at least one of carbon or nitrogen into the electrode.

In some implementations, injection depths of the at least one of carbon or nitrogen in the electrode are from 1 nm to 20 nm, respectively; and injection concentrations of the at least one of carbon or nitrogen in the electrode are from 1×10¹⁹ atom/cm³ to 5×10²⁰ atom/cm³, respectively.

In forms of the foregoing manufacturing method, a diffusion barrier layer is formed on a bottom portion and a side wall of a recess, and subsequently an electrode is formed on the diffusion barrier layer. In this way, during a process of forming the electrode or during a process of performing annealing on the electrode, a possibility that P-typed dopants or N-typed dopants in the electrode are diffused to a channel region may be reduced so as to possibly avoid low doping of the channel region, thereby avoiding decreasing a charge carrier mobility of the channel region. Therefore, a stronger working current (that is, a channel current) may be generated when the semiconductor device is working, the SCE may be improved, and a leakage current may be decreased, so as to improve performance of the device.

The exemplary embodiments and implementations of the present disclosure are described in detail below with reference to the accompanying drawings, so that other features and advantages of the present disclosure become clear.

### BRIEF DESCRIPTION OF THE DRAWINGS

The accompanying drawings which constitute a part of the specification illustrate embodiments and implementations of the present disclosure and, together with the description, serve to explain the principles of the present disclosure.

With reference to the accompanying drawings, the present disclosure may be understood more clearly according to the following detailed description, where:

FIG. 1 is a flowchart of a method for manufacturing a semiconductor device;

FIG. 2 is a sectional diagram that schematically illustrates a structure at a phase of a manufacturing process of a semiconductor device;

FIG. 3 is a sectional diagram that schematically illustrates a structure at a phase of a manufacturing process of a semiconductor device;

FIG. 4 is a sectional diagram that schematically illustrates a structure at a phase of a manufacturing process of a semiconductor device;

FIG. 5 is a sectional diagram that schematically illustrates a structure at a phase of a manufacturing process of a semiconductor device;

FIG. 6 is a sectional diagram that schematically illustrates a structure at a phase of a manufacturing process of a semiconductor device;

FIG. 7A is a sectional diagram that schematically illustrates a structure at a phase of a manufacturing process of a semiconductor device;

FIG. 7B is a sectional diagram that schematically illustrates a structure at a phase of a manufacturing process of a semiconductor device;

FIG. 8A is a sectional diagram that schematically illustrates a structure at a phase of a manufacturing process of a semiconductor device; and

FIG. 8B is a sectional diagram that schematically illustrates a structure at a phase of a manufacturing process of a semiconductor device.

### DETAILED DESCRIPTION

Exemplary embodiments and implementations of the present disclosure are described in detail with reference to the accompanying drawings. It should be noted that unless being described in detail, relative layouts, mathematical expressions, and numeric values of components and steps described in these embodiments do not limit the scope of the present disclosure.

Meanwhile, it should be understood that for ease of description, sizes of the parts shown in the accompanying drawings are not drawn according to an actual proportional relationship.

The following description about at least one embodiment is for illustration purposes, and should not be used as a limitation on the present disclosure and applications or uses of the present disclosure.

Technologies, methods, and devices that are known by a person of ordinary skill in the related fields may not be discussed in detail. However, in proper cases, the technologies, methods, and devices should be considered as a part of the description.

In all examples shown and discussed herein, any specific value should be considered as exemplary only rather than as a limitation. Therefore, other examples of exemplary embodiments and implementations may have different values.

It should be noted that similar reference signs and letters represent similar items in the following accompanying drawings. Therefore, once an item is defined in a figure, the item needs not to be further discussed in the subsequent figures.

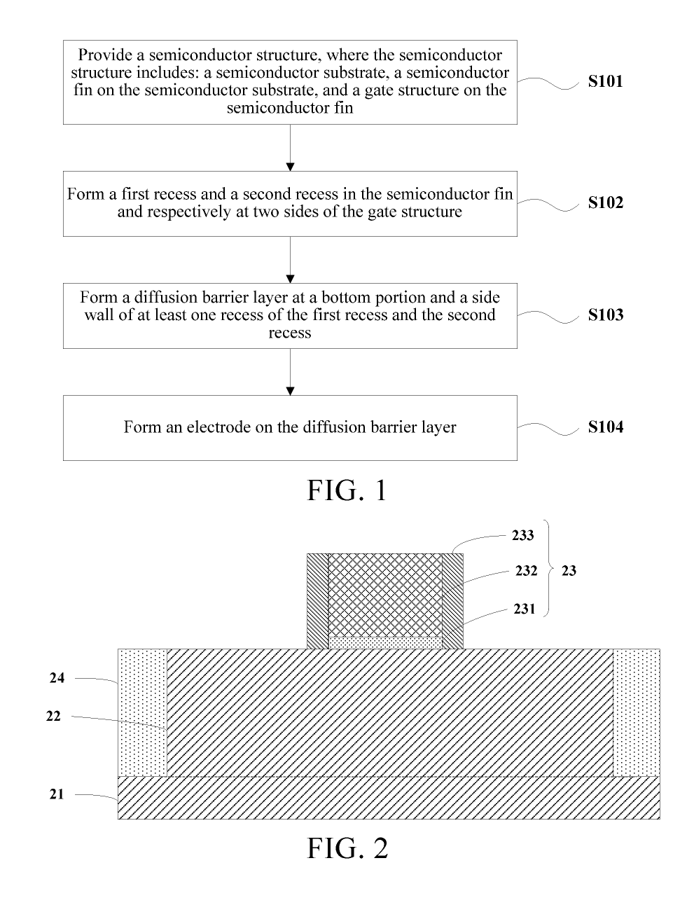

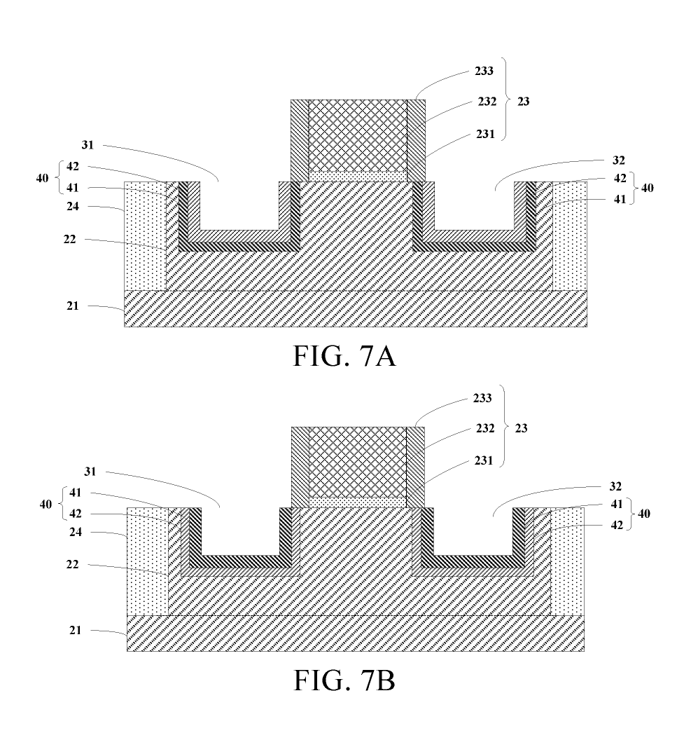

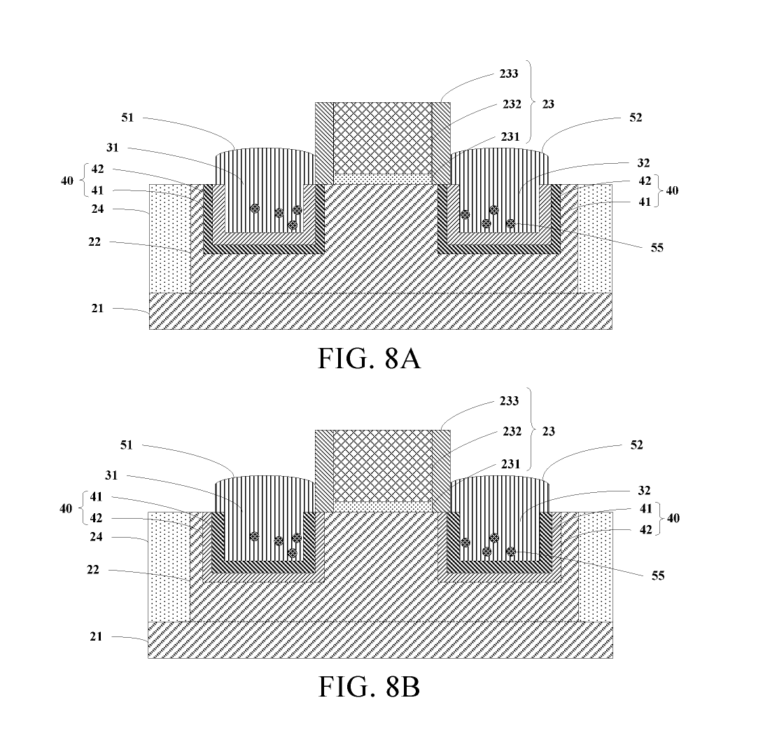

FIG. 1 is a flowchart of one form of a method for manufacturing a semiconductor device. FIG. 2 to FIG. 6, FIG. 7A, FIG. 7B, FIG. 8A and FIG. 8B are sectional diagrams that schematically illustrate structures at multiple phases of a manufacturing process of a semiconductor device. A manufacturing process of a semiconductor device according to some forms of the present disclosure is described below in detail with reference to FIG. 1, FIG. 2 to FIG. 6, FIG. 7A, FIG. 7B, FIG. 8A and FIG. 8B.

As shown in FIG. 1, in step S101, a semiconductor structure is provided. The semiconductor structure includes: a semiconductor substrate, a semiconductor fin on the semiconductor substrate, and a gate structure on the semiconductor fin.

FIG. 2 is a sectional diagram that schematically illustrates a structure in step S101 of a method for manufacturing a semiconductor device. As shown in FIG. 2, a semiconductor structure is provided. The semiconductor structure may include: a semiconductor substrate (for example, a silicon substrate) 21, a semiconductor fin (for example, a silicon fin) 22 on the semiconductor substrate 21, and a gate structure 23 on the semiconductor fin 22. It should be noted that the dotted lines shown in the figure only are boundary lines for ease of description and showing. Actually, these dotted lines do not necessarily exist.

In some implementations, the gate structure 23 may include: a gate dielectric layer 231 on a portion of the semiconductor fin 22, a gate 232 on the gate dielectric layer 231, and a spacer 233 on a side surface of the gate 232. Material of the gate dielectric layer 231 may include: silicon dioxide and/or a high dielectric constant material (for example, hafnium dioxide). Material of the gate 232 may include: polysilicon and/or a metal such as tungsten. Material of the spacer 233 may include: silicon dioxide and/or silicon nitride. Optionally, the gate structure may further include: a work function regulating layer (not shown in the figure) between the gate dielectric layer 231 and the gate 232. The work function regulating layer may be configured to regulate a threshold voltage of a device.

Optionally, as shown in FIG. 2, the semiconductor structure may further include a trench isolation portion 24 that is on the semiconductor substrate 21 and around the semiconductor fin 22. For example, the trench isolation portion 24 may include: a trench around the semiconductor fin 22 and a trench insulator layer filling the trench (for example, silicon dioxide).

Back to FIG. 1, in step S102, a first recess and a second recess are formed in the semiconductor fin and respectively at two sides of the gate structure.

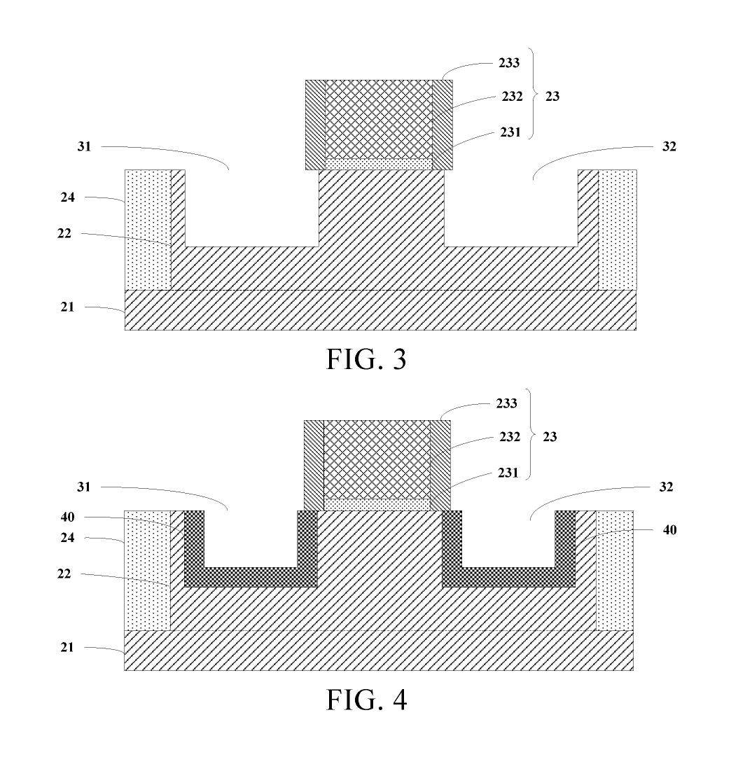

FIG. 3 is a sectional diagram that schematically illustrates a structure in step S102 of a method for manufacturing a semiconductor device. As shown in FIG. 3, for example, a first recess 31 and a second recess 32 are formed, by means of the etching process, in the semiconductor fin 22 and respectively at two sides of the gate structure 23. For example, as shown in FIG. 3, etching may be performed to a portion below the spacer 233, so as to increase sizes of the first recess 31 and the second recess 32 as possible, helping to subsequently form a source and a drain of possibly larger sizes.

Referring again to FIG. 1, in step S103, a diffusion barrier layer is formed on a bottom portion and a side wall of at least one recess of the first recess or the second recess.

FIG. 4 is a sectional diagram that schematically illustrates a structure in step S103 of a method for manufacturing a semiconductor device. As shown in FIG. 4, step S103 may include: forming a diffusion barrier layer 40 on bottom portions and side walls of the first recess 31 and the second recess 32 (the two recesses). In some implementations, the diffusion barrier layer 40 may include carbon and/or nitrogen. For example, the carbon and/or the nitrogen herein may be stored in the diffusion barrier layer 40 in a form of dopants (for example, may be a form of atoms, molecules, ions, or other elements).

In some implementations of the present disclosure, in the diffusion barrier layer, the carbon may effectively block boron and phosphorus, and the nitrogen may relatively effectively block boron. Therefore, doping the carbon and/or the nitrogen into the diffusion barrier layer may relatively effectively block P-typed dopants (such as boron) or N-typed dopants (such as phosphorus) contained in the source and the drain that are subsequently formed, and may possibly prevent the dopants from being diffused to a channel region, so as to possibly avoid decreasing a charge carrier mobility of the channel region, thereby improving performance of the device. Herein, if the formed semiconductor device is a PMOS device, the source and the drain may be doped with boron. Therefore, the diffusion barrier layer herein may be doped with at least one of carbon or nitrogen. If the formed semiconductor device is an NMOS device, the source and the drain may be doped with phosphorus. Therefore, the diffusion barrier layer herein may be doped with carbon, and certainly, nitrogen may also be doped in addition to carbon.

In some implementations, in the diffusion barrier layer, a doping density of the carbon may be from 1×10¹⁸ atom/cm³ to 1×10²⁰ atom/cm³ (for example, 1×10¹⁹ atom/cm³ or 5×10¹⁹ atom/cm³). In some implementations, in the diffusion barrier layer, a doping density of the nitrogen may be from 1×10¹⁹ atom/cm³ to 1×10²⁰ atom/cm³ (for example, 5×10¹⁹ atom/cm³).

In some implementations, a thickness range of the diffusion barrier layer may be from 8 nm to 35 nm. For example, the thickness of the diffusion barrier layer may be 10 nm, 20 nm, or 30 nm.

It should be noted that although FIG. 4 shows that the diffusion barrier layer is formed in both the first recess and the second recess, the scope of the present disclosure is not limited thereto. For example, the diffusion barrier layer may also be formed in one of the first recess or the second recess.

In some implementations, the material of the diffusion barrier layer 40 may include silicon. For example, an epitaxial growth is performed in the first recess 31 and the second recess 32 by using Silane (SiH₄), and a compound gas containing carbon (for example, methane (CH₄)) and/or a compound gas containing nitrogen (for example, ammonia (NH₃)) is doped into the SiH₄ gas in a process of the epitaxial growth, so that the carbon and/or the nitrogen is doped into a formed silicon epitaxial body, so as to form the diffusion barrier layer.

Optionally, in the epitaxial process, the diffusion barrier layer of a required conductivity type may be further obtained by mean of in-situ doping. For example, borane or phosphine may be doped in the SiH₄ gas, so that the diffusion barrier layer that is formed in an epitaxial manner has a corresponding conductivity type. Doping into borane may enable the diffusion barrier layer to have a P-typed conductivity type, and doping into phosphine may enable the diffusion barrier layer to have an N-typed conductivity type. For example, in a P-typed diffusion barrier layer, a doping density of boron may be from 1×10¹⁸ atom/cm³ to 5×10¹⁹ atom/cm³ (for example, 1×10¹⁹ atom/cm³). Further for example, in an N-typed diffusion barrier layer, a doping density of phosphorus may be from 1×10¹⁸ atom/cm³ to 5×10¹⁹ atom/cm³ (for example, 1×10¹⁹ atom/cm³). It should be noted that in the epitaxial process, a corresponding conductivity type is obtained by doping borane or phosphine. In addition, in forms of the present disclosure, the corresponding conductivity type may also be obtained using another group III element or group V element (for example, arsenic) as a dopant. Accordingly, the scope of the present disclosure is not limited thereto. In other implementations, the borane or the phosphine may not be doped into the SiH₄ gas. That is, the diffusion barrier layer is not in-situ doped.

In other implementations, as shown in FIG. 7A and FIG. 7B, the diffusion barrier layer 40 may include: a first diffusion barrier layer 41 containing nitrogen and/or a second diffusion barrier layer 42 containing carbon. That is, the diffusion barrier layer may be a first diffusion barrier layer containing nitrogen, or may be a second diffusion barrier layer containing carbon, or may be a combination layer of the first diffusion barrier layer containing nitrogen and the second diffusion barrier layer containing carbon.

FIG. 7A schematically illustrates a structure in a step of forming, at bottom portions and side walls of a first recess and a second recess, a diffusion barrier layer according to one form of the present disclosure. The step of forming the diffusion barrier layer may include: forming, by means of an epitaxial process, the first diffusion barrier layer 41 at bottom portions and side walls of a first recess 31 and a second recess 32, and forming, by means of the epitaxial process, the second diffusion barrier layer 42 on the first diffusion barrier layer 41.

FIG. 7B schematically illustrates a structure in a step of forming, at bottom portions and side walls of a first recess and a second recess, a diffusion barrier layer according to another form of the present disclosure. The step of the forming the diffusion barrier layer may include: forming, by means of an epitaxial process, the second diffusion barrier layer 42 at bottom portions and side walls of a first recess 31 and a second recess 32, and forming, by means of the epitaxial process, the first diffusion barrier layer 41 on the second diffusion barrier layer 42.

In some implementations, a first diffusion barrier layer 41 containing nitrogen may be formed by means of an epitaxial growth by using SiH₄ and a compound gas containing nitrogen. In some implementations, a second diffusion barrier layer 42 containing carbon may be formed by means of an epitaxial growth by using SiH₄ and a compound gas containing carbon.

In some implementations, a thickness range of the first diffusion barrier layer 41 may be from 4 nm to 16 nm. For example, the thickness of the first diffusion barrier layer 41 may be 8 nm, 10 nm, or 14 nm. In some implementations, a thickness range of the second diffusion barrier layer 42 may be from 4 nm to 16 nm. For example, the thickness of the second diffusion barrier layer 42 may be 8 nm, 10 nm, or 14 nm.

Referring again to FIG. 1, in step S104, an electrode is formed on the diffusion barrier layer.

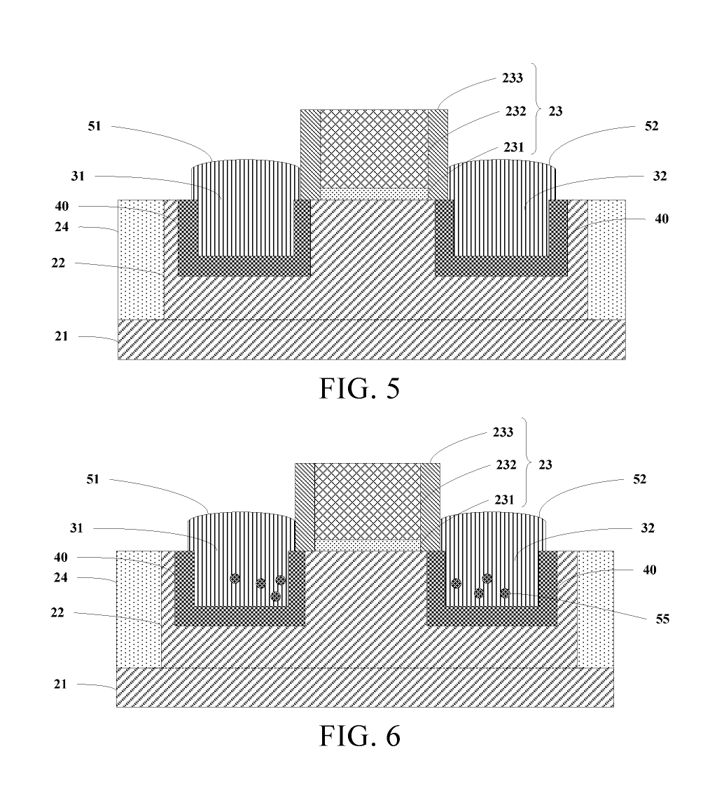

FIG. 5 is a sectional diagram that schematically illustrates a structure in step S104 of a method for manufacturing a semiconductor device. As shown in FIG. 5, for example, the electrode may be formed on the diffusion barrier layer 40 by means of an epitaxial process. For example, the electrode may include: a raised source 51 that fills the first recess 31 and a raised drain 52 that fills the second recess 32. In some implementations, as shown in FIG. 5, step S104 may include: forming, on the diffusion barrier layer 40, the raised source 51 that fills the first recess 31, and forming, on the diffusion barrier layer 40, the raised drain 52 that fills the second recess 32.

In some implementations of the present disclosure, materials of the source 51 and the drain 52 may include silicon-germanium or carborundum. In some implementations, a process of forming the source and the drain may include: first forming, on the diffusion barrier layer 40 by means of an epitaxial process, a filling portion of the source that fills the first recess 31 and a filling portion of the drain that fills the second recess 32; and then forming a raised portion of the source and a raised portion of the drain by means of epitaxy at the filling portion of the source and the filling portion of the drain, respectively, so as to form the source 51 and the drain 52. In other implementations, the raised source and drain may be directly formed by means of the epitaxial process, instead of forming the source and the drain in two steps by means of epitaxy as described in the foregoing implementations.

In some implementations, a conductivity type of the diffusion barrier layer 40 is the same as a conductivity type of the electrode (for example, the source 51 and the drain 52). For example, the source and the drain are P-typed, and the diffusion barrier layer is also P-typed. Alternatively, the source and the drain are N-typed, and the diffusion barrier layer is also N-typed.

In some implementations, after the electrode (for example, the source and the drain) is formed, the foregoing manufacturing method may further include: performing an annealing processing, so as to activate dopants (for example, P-typed dopants or N-typed dopants) in the electrode.

Above, implementations of a method for manufacturing a semiconductor device are provided. In forms of the manufacturing method, a diffusion barrier layer is formed in a recess, and subsequently an electrode is formed on the diffusion barrier layer. In this way, during a process of forming the electrode or during a process of performing annealing on the electrode, a possibility that P-typed dopants or N-typed dopants in the electrode are diffused to a channel region (below a gate structure and between the source and the drain) may be reduced as possible, so as to avoid low doping of the channel region, thereby avoiding decreasing a charge carrier mobility of the channel region. Therefore, a stronger working current (that is, a channel current) may be generated when the semiconductor device is working, the SCE (or the reverse short channel effect) may be improved, and a leakage current may be decreased, so as to improve performance of the device.

In addition, because the diffusion barrier layer contains carbon and/or nitrogen, the carbon and/or the nitrogen may be mismatched with crystal lattices of silicon (for example, the channel region), separately. Therefore, the diffusion barrier layer may further enhance a tensile stress of the channel region, so as to improve performance of the device.

In some implementations, during the process of forming the diffusion barrier layer, the diffusion barrier layer may be performed with P-typed or N-typed doping, or the diffusion barrier layer may not be performed with the P-typed or the N-typed doping. When the diffusion barrier layer is not performed with the P-typed or the N-typed doping, during a subsequent process of forming the electrode (the source and the drain) by means of epitaxy or during a subsequent process of performing an annealing processing on the electrode, it is possible that some of the P-typed dopants or the N-typed dopants in the electrode enter the diffusion barrier layer, so that the diffusion barrier layer has a corresponding conductivity type. This helps to reduce a series resistance and improve performance of the device.

In some implementations, as shown in FIG. 6, FIG. 8A, or FIG. 8B, the foregoing manufacturing method may further include: performing an ion injection on the electrode (for example, the source 51 and the drain 52), so as to inject carbon and/or nitrogen (for example, a carbon dopant 55 or a nitrogen dopant 55 shown in FIG. 6, FIG. 8A, or FIG. 8B) into the electrode. For example, the carbon and/or the nitrogen herein may be stored in the electrode in a form of dopants (for example, may be a form of atoms, molecules, ions, or other elements). Injecting carbon and/or nitrogen into the electrode may further reduce a possibility that the P-typed dopants or the N-typed dopants in the electrode are diffused to a channel region, so as to further improve performance of the device.

In some implementations, the foregoing process of performing an ion injection on the electrode may include: performing an ion injection on the carbon and/or the nitrogen after epitaxy is performed on a portion of the electrode (that is, the source and the drain), and then performing epitaxy to form an entire electrode.

In some implementations, injection depths of the carbon and/or the nitrogen in the electrode (for example, the source 51 and the drain 52) may be from 1 nm to 20 nm (for example, 5 nm or 10 nm), respectively. In some implementations, injection concentrations of the carbon and/or the nitrogen in the electrode may be from 1×10¹⁹ atom/cm³ to 5×10²⁰ (for example, 1×10²⁰ atom/cm³) atom/cm³, respectively.

The present disclosure further provides a semiconductor device. As shown in FIG. 6, the semiconductor device may include: a semiconductor substrate 21, a semiconductor fin 22 on the semiconductor substrate 21, and a gate structure 23 on the semiconductor fin 22. The gate structure 23 may include: a gate dielectric layer 231 on a portion of the semiconductor fin 22, a gate 232 on the gate dielectric layer 231, and a spacer 233 on a side surface of the gate 232. Optionally, the gate structure may further include: a work function regulating layer (not shown in the figure) between the gate dielectric layer 231 and the gate 232. The work function regulating layer may be configured to regulate a threshold voltage of the semiconductor device.

As shown in FIG. 6, the semiconductor device may further include: a first recess 31 and a second recess 32 that are in the semiconductor fin 22 and respectively at two sides of the gate structure 23.

For example, as shown in FIG. 6, the semiconductor device may further include: a diffusion barrier layer 40 located at a bottom portion and a side wall of at least one recess of the first recess 31 and the second recess 32. As shown in FIG. 6, the diffusion barrier layer 40 is formed on the bottom portions and the side walls of the first recess 31 and the second recess 32. The diffusion barrier layer 40 may contain carbon and/or nitrogen.

In some implementations, in the diffusion barrier layer, a doping density of the carbon may be from 1×10¹⁸ atom/cm³ to 1×10²⁰ atom/cm³ (for example, 1×10¹⁹ atom/cm³ or 5×10¹⁹ atom/cm³). In some implementations, in the diffusion barrier layer, a doping density of the nitrogen may be from 1×10¹⁹ atom/cm³ to 1×10²⁰ atom/cm³ (for example, 5×10¹⁹ atom/cm³). In some implementations, a thickness range of the diffusion barrier layer 40 may be from 8 nm to 35 nm. For example, the thickness of the diffusion barrier layer may be 10 nm, 20 nm, or 30 nm.

In some implementations, as shown in FIG. 8A or FIG. 8B, the diffusion barrier layer 40 may include: a first diffusion barrier layer 41 containing nitrogen and/or a second diffusion barrier layer 42 containing carbon.

For example, as shown in FIG. 8A, the first diffusion barrier layer 41 is on the bottom portions and the side walls of the first recess 31 and the second recess 32, and the second diffusion barrier layer 42 is on the first diffusion barrier layer 41. The first diffusion barrier layer 41 containing nitrogen is disposed on a bottom portion and a side wall of a recess, so that P-typed dopants or N-typed dopants that may possibly exist in the first diffusion barrier layer 41 are slightly diffused to a portion of the semiconductor fin below the recess. Therefore, a graded junction rather than an abrupt junction may be formed with the semiconductor fin, and a series resistance is reduced, so as to improve performance of the device.

Further, as shown in FIG. 8B for example, the second diffusion barrier layer 42 is on the bottom portions and the side walls of the first recess 31 and the second recess 32, and the first diffusion barrier layer 41 is on the second diffusion barrier layer 42.

In some implementations, a thickness range of the first diffusion barrier layer 41 may be from 4 nm to 16 nm. For example, the thickness of the first diffusion barrier layer 41 may be 8 nm, 10 nm, or 14 nm. In some implementations, a thickness range of the second diffusion barrier layer 42 may be from 4 nm to 16 nm. For example, the thickness of the second diffusion barrier layer 42 may be 8 nm, 10 nm, or 14 nm.

For example, as shown in FIG. 6, the semiconductor device may further include: an electrode on the diffusion barrier layer 40. In some implementations, the electrode may include: a raised source 51 that is on the diffusion barrier layer 40 and fills the first recess 31, and a raised drain 52 that is on the diffusion barrier layer 40 and fills the second recess 32. A conductivity type of the diffusion barrier layer 40 is same to that of the electrode.

In implementations described above, the semiconductor device includes a diffusion barrier layer on a bottom portion and a side wall of a recess, where an electrode is formed on the diffusion barrier layer, and the diffusion barrier layer may possibly reduce a possibility that P-typed dopants or N-typed dopants in the electrode are diffused to a channel region, and possibly avoid low doping of the channel region, so as to avoid decreasing a charge carrier mobility of the channel region. Therefore, a stronger working current (that is, a channel current) may be generated when the semiconductor device is working, the SCE (or the reverse short channel effect) may be improved, and a leakage current may be decreased, so as to improve performance of the device.

In addition, because the diffusion barrier layer contains carbon and/or nitrogen, the carbon and/the nitrogen may be mismatched with crystal lattices of silicon (for example, the channel region), separately. Therefore, the diffusion barrier layer may further enhance a tensile stress of the channel region, so as to improve performance of the device.

In some implementations, the electrode (for example, the source and the drain) may include: carbon and/or nitrogen (for example, the carbon dopant 55 or the nitrogen dopant 55 shown in FIG. 6, FIG. 8A, or FIG. 8B). Injecting carbon and/or nitrogen into the electrode may further reduce a possibility that the P-typed dopants or the N-typed dopants in the electrode are diffused to a channel region, so as to further improve performance of the device.

In some implementations, injection depths of the carbon and/or the nitrogen in the electrode (for example, the source 51 and the drain 52) may be from 1 nm to 20 nm (for example, 5 nm or 10 nm), respectively. In some implementations, injection concentrations of the carbon and/or the nitrogen in the electrode may be from 1×10¹⁹ atom/cm³ to 5×10²⁰ (for example, 1×10²⁰ atom/cm³) atom/cm³, respectively.

In some implementations, as shown in FIG. 6, the semiconductor device may further include: a trench isolation portion 24 that is on the semiconductor substrate 21 and around the semiconductor fin 22. For example, the trench isolation portion may include: a trench around the semiconductor fin 22 and a trench insulator layer filling the trench (for example, silicon dioxide).

Embodiment and implementations of the present disclosure have been described above in detail. To avoid obstructing the ideas of the present disclosure, some details generally known in the art are not described. According to the foregoing descriptions, a person skilled in the art will understand how to implement the technical solutions disclosed herein.

Some specific embodiments and implementations of the present disclosure are described in detail through examples. However, a person skilled in the art will understand that the foregoing examples and implementations are merely for illustration, and are not intended to limit the scope of the present disclosure. A person skilled in the art will understand that the foregoing embodiments and implementations may be modified without departing from the scope and spirit of the present disclosure. The scope of the present disclosure is defined by the appended claims.

What is claimed is:

1. A semiconductor device, comprising:
a semiconductor substrate;
a semiconductor fin positioned on the semiconductor substrate;
a gate structure positioned on the semiconductor fin;
a first recess and a second recess defined in the semiconductor fin and positioned, respectively, at two sides of the gate structure;
a diffusion barrier layer located at a bottom portion and a side wall of at least one recess of the first recess or the second recess; and
an electrode positioned on the diffusion barrier layer.

2. The semiconductor device according to claim 1, wherein the diffusion barrier layer comprises at least one of carbon or nitrogen.

3. The semiconductor device according to claim 2, wherein:
in the diffusion barrier layer, a doping density of the carbon is from 1×10¹⁸ atom/cm³ to 1×10²⁰ atom/cm³; and
in the diffusion barrier layer, a doping density of the nitrogen is from 1×10¹⁹ atom/cm³ to 1×10²⁰ atom/cm³.

4. The semiconductor device according to claim 1, wherein:
the diffusion barrier layer is formed at bottom portions and side walls of the first recess and the second recess; and
the electrode comprises:
a raised source that is on the diffusion barrier layer and fills the first recess, and
a raised drain that is on the diffusion barrier layer and fills the second recess.

5. The semiconductor device according to claim 4, wherein the diffusion barrier layer comprises:
at least one of a first diffusion barrier layer containing nitrogen or a second diffusion barrier layer containing carbon.

6. The semiconductor device according to claim 5, wherein:
the first diffusion barrier layer is at the bottom portions and the side walls of the first recess and the second recess, and the second diffusion barrier layer is on the first diffusion barrier layer; or
the second diffusion barrier layer is at the bottom portions and the side walls of the first recess and the second recess, and the first diffusion barrier layer is on the second diffusion barrier layer.

7. The semiconductor device according to claim 1, wherein a conductivity type of the diffusion barrier layer is the same as a conductivity type of the electrode.

8. The semiconductor device according to claim 6, wherein:
a thickness range of the diffusion barrier layer is from 8 nm to 35 nm;
a thickness range of the first diffusion barrier layer is from 4 nm to 16 nm; and
a thickness range of the second diffusion barrier layer is from 4 nm to 16 nm.

9. The semiconductor device according to claim 1, wherein the gate structure comprises:
a gate dielectric layer on a portion of the semiconductor fin,
a gate positioned on the gate dielectric layer, and
a spacer positioned on a side surface of the gate.

10. The semiconductor device according to claim 1, wherein the electrode comprises at least one of carbon or nitrogen.

11. The semiconductor device according to claim 10, wherein:
injection depths of the carbon and/or the nitrogen in the electrode are from 1 nm to 20 nm, respectively; and
injection concentrations of the carbon and/or the nitrogen in the electrode are from 1×10¹⁹ atom/cm³ to 5×10²⁰ atom/cm³, respectively.

12. A method for manufacturing a semiconductor device, comprising:
providing a semiconductor structure, wherein the semiconductor structure comprises:
a semiconductor substrate,
a semiconductor fin positioned on the semiconductor substrate, and
a gate structure positioned on the semiconductor fin;
forming a first recess and a second recess in the semiconductor fin and respectively at two sides of the gate structure;
forming a diffusion barrier layer at a bottom portion and a side wall of at least one recess of the first recess or the second recess; and
forming an electrode on the diffusion barrier layer.

13. The method according to claim 12, wherein the diffusion barrier layer comprises at least one of carbon or nitrogen.

14. The method according to claim 13, wherein:
in the diffusion barrier layer, a doping density of the carbon is from 1×10¹⁸ atom/cm³ to 1×10²⁰ atom/cm³; and
in the diffusion barrier layer, a doping density of the nitrogen is from 1×10¹⁹ atom/cm³ to 1×10²⁰ atom/cm³.

15. The method according to claim 12, wherein:
the step of the forming a diffusion barrier layer at a bottom portion and a side wall of at least one recess of the first recess or the second recess comprises: forming the diffusion barrier layer at bottom portions and side walls of at least one of the first recess or the second recess; and
the step of the forming an electrode on the diffusion barrier layer comprises: forming, on the diffusion barrier layer, a raised source that fills the first recess, and forming, on the diffusion barrier layer, a raised drain that fills the second recess.

16. The method according to claim 15, wherein the diffusion barrier layer comprises:
at least one of a first diffusion barrier layer containing nitrogen or a second diffusion barrier layer containing carbon.

17. The method according to claim 16, wherein the step of forming the diffusion barrier layer at the bottom portions and the side walls of the first recess and the second recess comprises:
forming, by means of an epitaxial process, the first diffusion barrier layer at the bottom portions and the side walls of the first recess and the second recess, and forming, by means of the epitaxial process, the second diffusion barrier layer on the first diffusion barrier layer; or
forming, by means of the epitaxial process, the second diffusion barrier layer at the bottom portions and the side walls of the first recess and the second recess, and forming, by means of the epitaxial process, the first diffusion barrier layer on the second diffusion barrier layer.

18. The method according to claim 12, wherein a conductivity type of the diffusion barrier layer is the same as a conductivity type of the electrode.

19. The method according to claim 16, wherein:
a thickness range of the diffusion barrier layer is from 8 nm to 35 nm;
a thickness range of the first diffusion barrier layer is from 4 nm to 16 nm; and
a thickness range of the second diffusion barrier layer is from 4 nm to 16 nm.

20. The method according to claim 12, wherein the gate structure comprises:
a gate dielectric layer on a portion of the semiconductor fin,
a gate on the gate dielectric layer, and
a spacer on a side surface of the gate.

21. The method according to claim 12, further comprising:
performing an ion injection on the electrode, so as to inject at least one of carbon or nitrogen into the electrode.

22. The method according to claim 21, wherein:
injection depths of the at least one of carbon or nitrogen in the electrode are from 1 nm to 20 nm, respectively; and
injection concentrations of the at least one of carbon or the nitrogen in the electrode are from 1×10¹⁹ atom/cm³ to 5×10²⁰ atom/cm³, respectively.
